(19) United States
(12) Patent Application Publication
(10) Pub. No.: US 2025/0185467 A1
(43) Pub. Date: Jun. 5, 2025

(54) DISPLAY DEVICE AND METHOD OF MANUFACTURING THE SAME

(71) Applicant: Samsung Display Co., LTD., Yongin-si (KR)

(72) Inventor: Chun Gi YOU, Yongin-si (KR)

(21) Appl. No.: 18/887,418

(22) Filed: Sep. 17, 2024

(30) Foreign Application Priority Data
Dec. 4, 2023 (KR) 10-2023-0173813

(51) Int. Cl. H10K 59/122; H10K 59/12; H10K 59/80

(52) U.S. Cl. CPC H10K 59/122; H10K 59/1201; H10K 59/80515; H10K 59/80521

(57) ABSTRACT

A display device includes a pixel circuit layer; a plurality of connection electrodes spaced apart from each other on the pixel circuit layer and connected to a pixel circuit in the pixel circuit layer; a plurality of pixel electrodes directly on the plurality of connection electrodes to correspond one-to-one to the plurality of connection electrodes and spaced apart from each other; a spacer between two adjacent pixel electrodes among the plurality of pixel electrodes on the pixel circuit layer; and a pixel defining film between the spacer and the plurality of pixel electrodes and covering at least a side surface of each of the plurality of connection electrodes and the plurality of pixel electrodes, on the pixel circuit layer, wherein at least one trench recessed in a direction from an upper surface of the spacer toward the pixel circuit layer is defined in the spacer.

### CROSS-REFERENCE TO RELATED APPLICATION

The present application claims priority to and the benefit of Korean Patent Application No. 10-2023-0173813, filed on Dec. 4, 2023, in the Korean Intellectual Property Office, the entire disclosure of which is incorporated herein by reference.

### BACKGROUND

### 1. Field

Aspects of the present disclosure relate to a display device and a method of manufacturing the same.

### 2. Description of the Related Art

A display device includes a plurality of pixels. Each of the plurality of pixels may emit light, and the display device may display an image by combining the light emitted from the plurality of pixels.

The plurality of pixels may be disposed adjacent to each other. In this case, a lateral leakage current may occur between two adjacent pixels, which may cause color mixing and poor luminance between adjacent pixels.

The above information disclosed in this Background section is for enhancement of understanding of the background of the present disclosure, and therefore, it may contain information that does not constitute related (or prior) art.

### SUMMARY

Aspects of embodiments of the present disclosure are directed to a display device that may prevent a lateral leakage current, and a method of manufacturing said display device.

According to some embodiments of the present disclosure, there is provided a display device including: a pixel circuit layer; a plurality of connection electrodes spaced apart from each other on the pixel circuit layer and connected to a pixel circuit in the pixel circuit layer; a plurality of pixel electrodes directly on the plurality of connection electrodes to correspond one-to-one to the plurality of connection electrodes and spaced apart from each other; a spacer between two adjacent pixel electrodes among the plurality of pixel electrodes on the pixel circuit layer; and a pixel defining film between the spacer and the plurality of pixel electrodes and covering at least a side surface of each of the plurality of connection electrodes and the plurality of pixel electrodes, on the pixel circuit layer, wherein at least one trench recessed in a direction from an upper surface of the spacer toward the pixel circuit layer is defined in the spacer.

In some embodiments, each of the plurality of pixel electrodes completely overlaps a corresponding connection electrode among the plurality of connection electrodes in a plan view.

In some embodiments, the spacer is in direct contact with the pixel circuit layer.

In some embodiments, the pixel defining film is in direct contact with the pixel circuit layer between the spacer and the plurality of pixel electrodes.

In some embodiments, in a plan view, the trench extends in a direction crossing a separation direction of two adjacent pixel electrodes among the plurality of pixel electrodes.

In some embodiments, the display device further includes: an intermediate layer on the plurality of pixel electrodes and including at least one common layer entirely on the pixel circuit layer; and a common electrode layer on the intermediate layer.

In some embodiments, the common layer is disconnected in an area in which the trench is defined.

In some embodiments, the common electrode layer is disconnected in the area in which the trench is defined.

According to some embodiments of the present disclosure, there is provided a display device including: a pixel circuit layer; a plurality of pixel electrodes spaced apart from each other on the pixel circuit layer; a spacer between two adjacent pixel electrodes among the plurality of pixel electrodes on the pixel circuit layer; a spacer cover layer covering at least an upper surface of the spacer; and a pixel defining film between the spacer and the plurality of pixel electrodes and covering at least a side surface of each of the plurality of pixel electrodes, the pixel defining film being on the pixel circuit layer, wherein the spacer defines at least one trench recessed in a direction from the upper surface of the spacer toward the pixel circuit layer, and wherein the spacer cover layer defines an opening overlapping the trench, and wherein an undercut structure is defined between the spacer and the spacer cover layer.

In some embodiments, the spacer is in direct contact with the pixel circuit layer.

In some embodiments, the pixel defining film is in direct contact with the pixel circuit layer between the spacer and the plurality of pixel electrodes.

In some embodiments, in a plan view, the trench extends in a direction crossing a separation direction of two adjacent pixel electrodes among the plurality of pixel electrodes.

In some embodiments, the display device further includes: an intermediate layer on the plurality of pixel electrodes and including at least one common layer entirely on the pixel circuit layer; and a common electrode layer on the intermediate layer.

In some embodiments, the common layer is disconnected in an area in which the trench is defined.

In some embodiments, the common electrode layer is disconnected in the area in which the trench is defined.

According to some embodiments of the present disclosure, there is provided a method of manufacturing a display device, the method including: forming a spacer on a pixel circuit layer; entirely forming a first conductive layer, defining at least one slit pattern exposing a portion of the spacer, on the pixel circuit layer; forming a trench by etching the spacer exposed by the slit pattern; entirely forming a second conductive layer on the first conductive layer; forming, by patterning the first conductive layer and the second conductive layer, a plurality of connection electrodes spaced apart from each other with at least the spacer therebetween, and a plurality of pixel electrodes directly on the plurality of connection electrodes to correspond one-to-one to the plurality of connection electrodes; and forming a pixel defining film that is between the spacer and the plurality of pixel electrodes and covers at least a side surface of each of the plurality of connection electrodes and the plurality of pixel electrodes, the pixel defining film being on the pixel circuit layer.

In some embodiments, the method of manufacturing the display device further includes: forming an intermediate layer including at least one common layer entirely on the pixel circuit layer, the intermediate layer being on the plurality of pixel electrodes.

In some embodiments, the common layer is disconnected in an area in which the trench is defined.

In some embodiments, the method of manufacturing the display device further includes: forming a common electrode layer on the intermediate layer.

In some embodiments, the common electrode layer is disconnected in an area in which the trench is defined.

According to some embodiments of the present disclosure, there is provided a method of manufacturing a display device, the method including: forming a spacer on a pixel circuit layer; forming a spacer cover layer covering at least an upper surface of the spacer and defining at least one opening exposing at least a portion of the spacer, the spacer cover layer being on the pixel circuit layer; forming a trench by etching the spacer exposed by the opening; forming a plurality of pixel electrodes spaced apart from each other with at least the spacer therebetween; and forming a pixel defining film that is between the spacer and the plurality of pixel electrodes and covers at least a side surface of each of the plurality of pixel electrodes, the pixel defining film being on the pixel circuit layer, wherein an undercut structure is defined between the spacer and the spacer cover layer.

In some embodiments, the method of manufacturing the display device further includes: forming an intermediate layer including at least one common layer entirely on the pixel circuit layer, the intermediate layer being on the plurality of pixel electrodes.

In some embodiments, the common layer is disconnected in an area in which the trench is defined.

In some embodiments, the method of manufacturing the display device further includes: forming a common electrode layer on the intermediate layer.

In some embodiments, the common electrode layer is disconnected in an area in which the trench is defined.

The display device according to some embodiments of the present disclosure includes a spacer disposed between two adjacent pixel electrodes among a plurality of pixel electrodes, and at least one trench recessed in a direction from an upper surface of the spacer toward a pixel circuit layer may be defined in the spacer. The trench may serve to block a common layer, and thus, a lateral leakage current between two adjacent pixel electrodes among the plurality of pixel electrodes may be blocked.

According to some embodiments, the method of manufacturing the display device includes forming a plurality of pixel electrodes after forming a trench by etching a spacer. In this way, as the plurality of pixel electrodes are formed after forming the trench, the plurality of pixel electrodes may not be damaged by the etching process.

### BRIEF DESCRIPTION OF THE DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings.

FIG. 1 illustrates a top plan view of a display device according to some embodiments of the present disclosure.

FIG. 2 illustrates a circuit diagram of a pixel included in the display device of FIG. 1, according to some embodiments of the present disclosure.

FIG. 3 illustrates a cross-sectional view of an organic light emitting diode included in the pixel of FIG. 2, according to some embodiments of the present disclosure.

FIGS. 4 and 5 illustrate cross-sectional views of the organic light emitting diode of FIG. 3, according to some embodiments of the present disclosure.

FIG. 6 illustrates an enlarged top plan view of a portion of a display area of the display device of FIG. 1, according to some embodiments of the present disclosure.

FIG. 7 illustrates a cross-sectional view taken along the line X1-X1′ of FIG. 6, according to some embodiments of the present disclosure.

FIGS. 8 to 13 illustrate a method of manufacturing the display device of FIG. 7, according to some embodiments of the present disclosure.

FIG. 14 illustrates a cross-sectional view taken along the line X1-X1′ of FIG. 6, according to some other embodiments of the present disclosure.

FIGS. 15 to 21 illustrate a method of manufacturing the display device of FIG. 14, according to some embodiments of the present disclosure.

### DETAILED DESCRIPTION

Hereinafter, example embodiments of the present disclosure will be described in detail with reference to the accompanying drawings. The following description is intended to provide only a sufficient disclosure to enable the understanding of the operation of the invention, and any other disclosure is omitted to avoid obscuring the scope of the invention. In addition, the inventive concept may be embodied in different forms and is not limited to the embodiments set forth herein. The embodiments described herein are provided for the purpose of describing the technical concept of the invention in sufficient detail for those skilled in the art to easily practice it.

Throughout the specification, when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Although the terms first, second, etc. may be used herein to describe various constituent elements, these constituent elements should not be limited by these terms. These terms are used to distinguish one constituent element from another. Thus, a first constituent element discussed below could be termed a second constituent element without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

Various embodiments are described herein with reference to sectional illustrations that are schematic illustrations of idealized embodiments. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

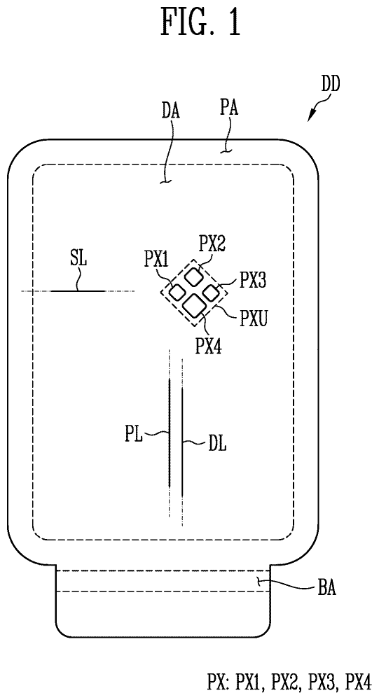

FIG. 1 illustrates a top plan view of a display device according to some embodiments of the present disclosure.

Referring to FIG. 1, a display device DD may include a display area DA and a peripheral area PA.

A plurality of pixels PX may be disposed in the display area DA. Each of the plurality of pixels PX may emit light, and the display device DD may display an image by combining the light emitted from the plurality of pixels PX.

In some embodiments, the pixels PX may include first to fourth pixels PX1, PX2, PX3, and PX4. The first to fourth pixels PX1, PX2, PX3, and PX4 may be disposed at or near four vertices of a virtual rhombus in a plan view.

The first to fourth pixels PX1, PX2, PX3, and PX4 may define a pixel unit PXU. A plurality of pixel units PXU may be provided in the display area DA. The pixel units PXU may be arranged in a regular pattern, thereby filling the display area DA without a gap.

In some other embodiments, the pixel unit PXU may include 2, 3, or 5 or more pixels. In addition, pixels configuring the pixel unit PXU may be variously disposed in a suitable manner in a plan view, differently from that shown in FIG. 1.

A plurality of signal lines may be disposed in the display area DA. The plurality of signal lines may be electrically connected to the pixels PX. For example, a scan line SL, a data line DL, and a power voltage line PL electrically connected to the pixels PX may be disposed in the display area DA. In this case, a plurality of scan lines SL, data lines DL, and power voltage lines PL may be provided in the display area DA.

The peripheral area PA may surround at least one side of the display area DA. A circuit portion, an electrode, and the like for providing an electrical signal to the pixels PX disposed in the display area DA may be disposed in the peripheral area PA.

For example, a data driver that generates a data voltage may be disposed in the peripheral area PA. The data driver may be connected to the data line DL disposed in the display area DA.

For another example, a scan driving circuit portion that generates a scan signal and a power voltage electrode portion that generates (or transmits) a power voltage may be disposed in the peripheral area PA. The scan driving circuit portion may be connected to the scan line SL, and the power voltage electrode portion may be connected to the power voltage line PL.

In some embodiments, the peripheral area PA may include a bending area BA. The bending area BA may be a region (e.g., an area) in which the display device DD is bent. For example, an area under the bending area BA shown in FIG. 1 may be disposed on a rear surface of the display device DD as the display device DD is bent in the bending area BA.

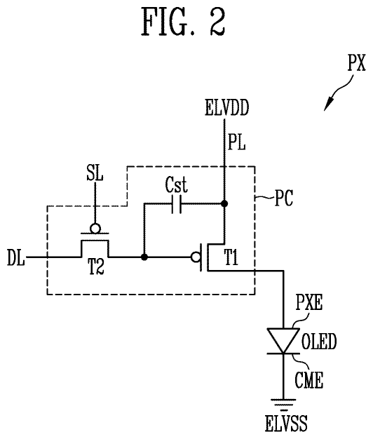

FIG. 2 illustrates a circuit diagram of a pixel included in the display device of FIG. 1, according to some embodiments of the present disclosure.

Referring to FIG. 2, the pixel PX may include a pixel circuit PC and an organic light emitting diode OLED electrically connected to the pixel circuit PC.

In some embodiments, the pixel circuit PC may include at least one transistor and at least one capacitor. For example, the pixel circuit PC may include a first transistor T1, a second transistor T2, and a storage capacitor Cst. However, this is an example, and the pixel circuit PC may include a larger number of transistors or a larger number of capacitors.

The second transistor T2 may be connected to the scan line SL and the data line DL to transmit a data signal inputted from the data line DL to the first transistor T1 based on a scan signal inputted from the scan line SL.

The storage capacitor Cst may be connected to the second transistor T2 and the power voltage line PL, and may store a voltage corresponding to a difference between a voltage received from the second transistor T2 and a first power supply voltage ELVDD supplied from the power voltage line PL.

The first transistor T1 may be connected to the power voltage line PL and the storage capacitor Cst to control a driving current flowing from the power voltage line PL to the organic light emitting diode OLED in response to a voltage value stored in the storage capacitor Cst.

The organic light emitting diode OLED may emit light with a predetermined luminance by the driving current. A pixel electrode PXE of the organic light emitting diode OLED may be connected to the first transistor T1 to receive the driving current. A common electrode layer CME of the organic light emitting diode OLED may receive a second power supply voltage ELVSS.

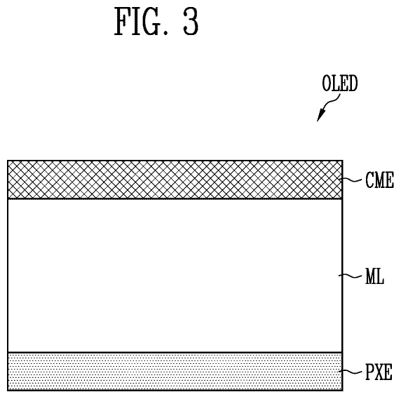

FIG. 3 illustrates a cross-sectional view of an organic light emitting diode included in the pixel of FIG. 2, according to some embodiments of the present disclosure.

Referring to FIG. 3, the organic light emitting diode OLED may include the pixel electrode PXE, the common electrode layer CME, and an intermediate layer ML interposed between the pixel electrode PXE and the common electrode layer CME.

In some embodiments, the pixel electrode PXE may include a conductive oxide. For example, the pixel electrode PXE may include at least one of an indium tin oxide (ITO), an indium zinc oxide (IZO), ZnO, In₂O₃, an indium gallium oxide (IGO), and an aluminum zinc oxide (AZO). In some other embodiments, the pixel electrode PXE may include a reflective layer. For example, the pixel electrode PXE may include at least one of silver, magnesium, aluminum, platinum, palladium, gold, nickel, neodymium, iridium, chromium, and a compound thereof. In some other embodiments, the pixel electrode PXE may have a multi-layer structure including the conductive oxide and/or the reflective layer. For example, the pixel electrode PXE may have a three-layer structure of ITO/Ag/ITO.

The common electrode layer CME may include a metal, an alloy, an electrically conductive compound, or any combination thereof having a low work function. For example, the common electrode layer CME may include lithium, silver magnesium, aluminum, aluminum-lithium, calcium, magnesium-indium, magnesium-silver, ytterbium (Yb), silver-etabium, ITO, IZO, or any combination thereof. The common electrode layer CME may be a transmissive electrode layer or a semi-transmissive electrode layer.

In some embodiments, the pixel electrode PXE may be referred to as an anode electrode, and the common electrode layer CME may be referred to as a cathode electrode.

The intermediate layer ML may include a high-molecular-weight or a low-molecular-weight organic material that emits light of a set or predetermined color. In addition to various suitable organic materials, the intermediate layer ML may further include a metal-containing compound such as an organometallic compound, an inorganic material such as a quantum dot, and the like.

In some embodiments, the intermediate layer ML may include one light emitting layer, and a first functional layer and/or a second functional layer disposed below and above the light emitting layer, respectively. The first functional layer may include, for example, a hole transport layer HTL and/or a hole injection layer HIL. The second functional layer may include, for example, an electron transport layer ETL and/or an electron injection layer EIL.

In some embodiments, the intermediate layer ML may include a charge generation layer CGL disposed between two or more light emitting units stacked between the pixel electrode PXE and the common electrode layer CME. The structure of the intermediate layer ML may be referred to as a tandem structure. As the intermediate layer ML has the tandem structure, color purity and luminous efficiency may be improved (e.g., increased).

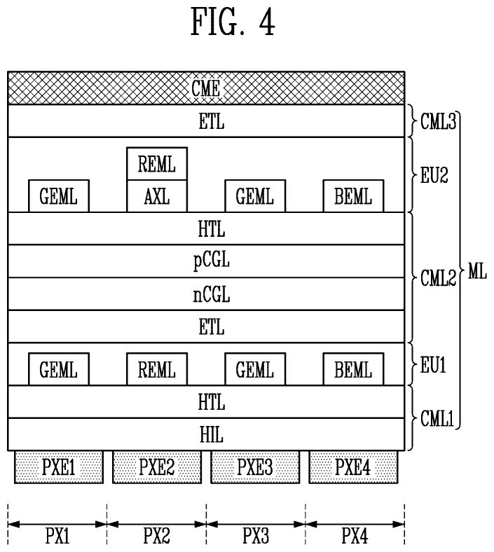

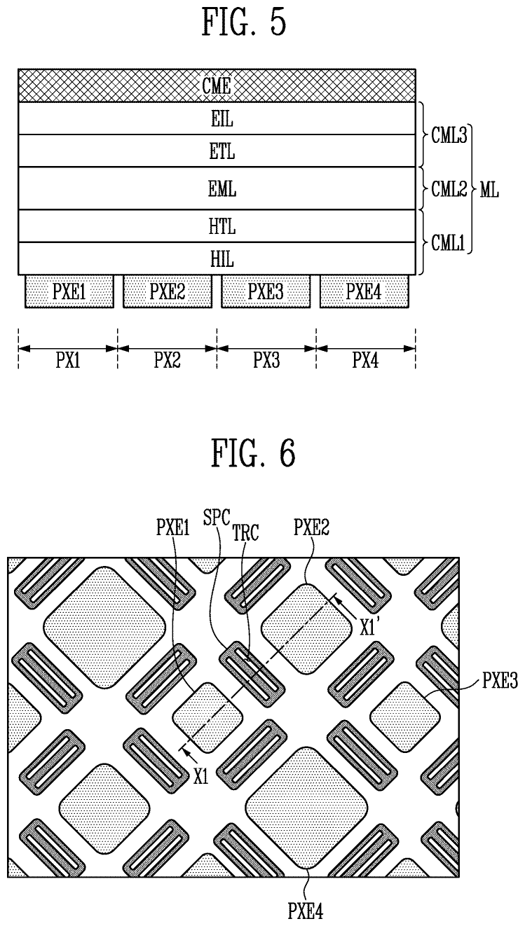

FIGS. 4 and 5 illustrate cross-sectional views of the organic light emitting diode of FIG. 3, according to some embodiments of the present disclosure.

Referring to FIG. 4, the first to fourth pixels PX1, PX2, PX3, and PX4 may include first to fourth pixel electrodes PXE1, PXE2, PXE3, and PXE4. Here, the pixel electrodes PXE1, PXE2, PXE3, and PXE4 may be disposed to be spaced apart from each other, and each of the pixel electrodes PXE1, PXE2, PXE3, and PXE4 may be provided one by one to a corresponding pixel among the first to fourth pixels PX1, PX2, PX3, and PX4.

The first to fourth pixels PX1, PX2, PX3, and PX4 may include the common electrode layer CME. The common electrode layer CME may be disposed to face the first to fourth pixel electrodes PXE1, PXE2, PXE3, and PXE4. The common electrode layer CME may be commonly provided to the first to fourth pixels PX1, PX2, PX3, and PX4. In other words, the first to fourth pixels PX1, PX2, PX3, and PX4 may share the common electrode layer CME.

The first to fourth pixels PX1, PX2, PX3, and PX4 may include the intermediate layer ML, which is interposed between the first to fourth pixel electrodes PXE1, PXE2, PXE3, and PXE4 and the common electrode layer CME.

In some embodiments, the intermediate layer ML may include a first common layer CML1, a first light emitting unit EU1, a second common layer CML2, a second light emitting unit EU2, and a third common layer CML3 that are sequentially stacked.

The first common layer CML1 may be commonly provided to the first to fourth pixels PX1, PX2, PX3, and PX4. The first common layer CML1 may include a hole injection layer HIL and a hole transport layer HTL.

The first light emitting unit EU1 may include a green light emitting layer GEML provided in the first pixel PX1, a red light emitting layer REML provided in the second pixel PX2, a green light emitting layer GEML provided in the third pixel PX3, and a blue light emitting layer BEML provided in the fourth pixel PX4. Here, the light emitting layers GEML, REML, and BEML provided to the pixels PX1, PX2, PX3, and PX4 may be disposed to be spaced apart from each other.

The second common layer CML2 may be commonly provided to the first to fourth pixels PX1, PX2, PX3, and PX4. The second common layer CML2 may include an electron transport layer ETL, a hole transport layer HTL, and a negative charge generation layer nCGL, and a positive charge generation layer pCGL interposed between the electron transport layer ETL and the hole transport layer HTL.

The negative charge generation layer nCGL may be an n-type charge generation layer. The negative charge generation layer nCGL may serve to supply electrons. For example, the negative charge generation layer nCGL may include a host including an organic material and a dopant including a metal material.

The positive charge generation layer pCGL may be a p-type charge generation layer. The positive charge generation layer pCGL may serve to supply holes. For example, the positive charge generation layer pCGL may include a host including an organic material and a dopant including a metal material.

The second light emitting unit EU2 may include a green light emitting layer GEML provided in the first pixel PX1, an auxiliary layer AXL and a red light emitting layer REML provided in the second pixel PX2, a green light emitting layer GEML provided in the third pixel PX3, and a blue light emitting layer BEML provided in the fourth pixel PX4. The auxiliary layer AXL provided in the second pixel PX2 is a layer added to adjust a resonance distance, and may include a resonance auxiliary material. For example, the auxiliary layer AXL may include the same or substantially the same material as the hole transport layer HTL.

FIG. 4 illustrates some embodiments in which the auxiliary layer AXL is provided only in the second pixel PX2 (and not in the first, third and fourth pixels PX1, PX3, and PX4), but the present disclosure is not limited thereto. For example, the auxiliary layer AXL may be provided in at least one of the first pixel PX1, the second pixel PX2, the third pixel PX3, and the fourth pixel PX4 to match the resonance distance of each of the first pixel PX1, the second pixel PX2, the third pixel PX3, and the fourth pixel PX4.

The third common layer CML3 may be commonly provided to the first to fourth pixels PX1, PX2, PX3, and PX4. The third common layer CML3 may include an electron transport layer ETL.

FIG. 4 illustrates some embodiments in which the intermediate layer ML includes three common layers CML1, CML2, and CML3 and two light emitting units EU1 and EU2, but the present disclosure is not limited thereto. The intermediate layer ML may include various numbers of common layers (for example, two or four or more common layers) and various numbers of light emitting units (for example, one or three or more light emitting units).

In this case, each of the common layers CML1, CML2, and CML3 may include more or fewer functional layers (for example, more or less of one of HIL, HTL, EIL, and ETL) and more or fewer charge generation layers (for example, more or less of one of pCGL and nCGL), to improve the light emitting efficiency of the organic light emitting diode OLED.

Referring to FIG. 5, the first to fourth pixels PX1, PX2, PX3, and PX4 may include the first to fourth pixel electrodes PXE1, PXE2, PXE3, and PXE4. Here, the pixel electrodes PXE1, PXE2, PXE3, and PXE4 may be disposed to be spaced apart from each other, and each of the pixel electrodes PXE1, PXE2, PXE3, and PXE4 may be provided one by one to a corresponding pixel among the first to fourth pixels PX1, PX2, PX3, and PX4 (i.e., the pixel electrodes PXE1, PXE2, PXE3, and PXE4 may have one-to-one correspondence to the first to fourth pixels PX1, PX2, PX3, and PX4).

The first to fourth pixels PX1, PX2, PX3, and PX4 may include a common electrode layer CME. The common electrode layer CME may be disposed to face the first to fourth pixel electrodes PXE1, PXE2, PXE3, and PXE4. The common electrode layer CME may be commonly provided to the first to fourth pixels PX1, PX2, PX3, and PX4. In other words, the first to fourth pixels PX1, PX2, PX3, and PX4 may share the common electrode layer CME.

The first to fourth pixels PX1, PX2, PX3, and PX4 may include the intermediate layer ML interposed between the first to fourth pixel electrodes PXE1, PXE2, PXE3, and PXE4 and the common electrode layer CME.

In some embodiments, the intermediate layer ML may include a first common layer CML1, a second common layer CML2, and a third common layer CML3 that are sequentially stacked.

The first common layer CML1 may be commonly provided to the first to fourth pixels PX1, PX2, PX3, and PX4. The first common layer CML1 may include a hole injection layer HIL and a hole transport layer HTL.

The second common layer CML2 may be commonly provided to the first to fourth pixels PX1, PX2, PX3, and PX4. The second common layer CML2 may include a light emitting layer EML. Here, unlike FIG. 4, the light emitting layer EML may be commonly provided to the pixels PX1, PX2, PX3, and PX4. That is, the light emitting layer EML may be provided in the form of a common layer.

The third common layer CML3 may be commonly provided to the first to fourth pixels PX1, PX2, PX3, and PX4. The third common layer CML3 may include an electron transport layer ETL and an electron injection layer EIL.

FIG. 5 illustrates some embodiments in which the intermediate layer ML includes three common layers CML1, CML2, and CML3, but the present disclosure is not limited thereto. The intermediate layer ML may include various numbers of common layers (for example, two or four or more common layers). In some examples, the intermediate layer ML may further include various numbers of light emitting units (for example, one or more light emitting units) described with reference to FIG. 4.

Each of the common layers CML1, CML2, and CML3 may include more or fewer functional layers (for example, more or less of one of HIL, HTL, EIL, and ETL) and may further include the charge generation layers (for example, pCGL and nCGL), to improve the light emitting efficiency of the organic light emitting diode OLED. In some examples, in addition to the second common layer CML2, a common layer including the light emitting layer EML commonly provided to the pixels PX1, PX2, PX3, and PX4 may be further provided.

In FIGS. 4 and 5, the organic light emitting diode OLED including the intermediate layer ML having at least one common layer has been described. Hereinafter, for better comprehension and ease of description, embodiments of the present disclosure will be described based on the structure of the organic light emitting diode OLED described with reference to FIG. 4. However, the present disclosure is not limited to the organic light emitting diode OLED structure of FIG. 4, and may be variously applied to an organic light emitting diode OLED including various suitable types of intermediate layers ML having at least one common layer.

FIG. 6 illustrates an enlarged top plan view of a portion of a display area of the display device of FIG. 1, according to some embodiments of the present disclosure.

Referring to FIG. 6, a plurality of pixel electrodes PXE1, PXE2, PXE3, and PXE4 and a spacer SPC may be disposed in the display area DA of FIG. 1.

The plurality of pixel electrodes PXE1, PXE2, PXE3, and PXE4 may be disposed to be spaced apart from each other. The plurality of pixel electrodes PXE1, PXE2, PXE3, and PXE4 may be provided one by one to a corresponding pixel among the pixels PX1, PX2, PX3, and PX4 described with reference to FIG. 1. For example, the first pixel (e.g., PX1 in FIG. 1) may include the first pixel electrode PXE1, the second pixel (e.g., PX2 in FIG. 1) may include the second pixel electrode PXE2, the third pixel (e.g., PX3 in FIG. 1) may include the third pixel electrode PXE3, and the fourth pixel (e.g., PX4 in FIG. 1) may include the fourth pixel electrode PXE4.

The spacer SPC may be disposed between two adjacent pixel electrodes among the plurality of pixel electrodes PXE1, PXE2, PXE3, and PXE4. At least one trench (e.g., an elongated opening in a plan view) TRC may be defined in the spacer SPC. The trench TRC may also be disposed between two adjacent pixel electrodes among the plurality of pixel electrodes PXE1, PXE2, PXE3, and PXE4. The trench TRC may extend in a direction crossing a separation direction of two adjacent pixel electrodes among the plurality of pixel electrodes PXE1, PXE2, PXE3, and PXE4. Accordingly, the trench TRC may serve to disconnect the common layer included in the intermediate layer ML described with reference to FIG. 3 to FIG. 5 between two adjacent pixel electrodes. In some examples, each spacer SPC may define two parallel trenches TRC.

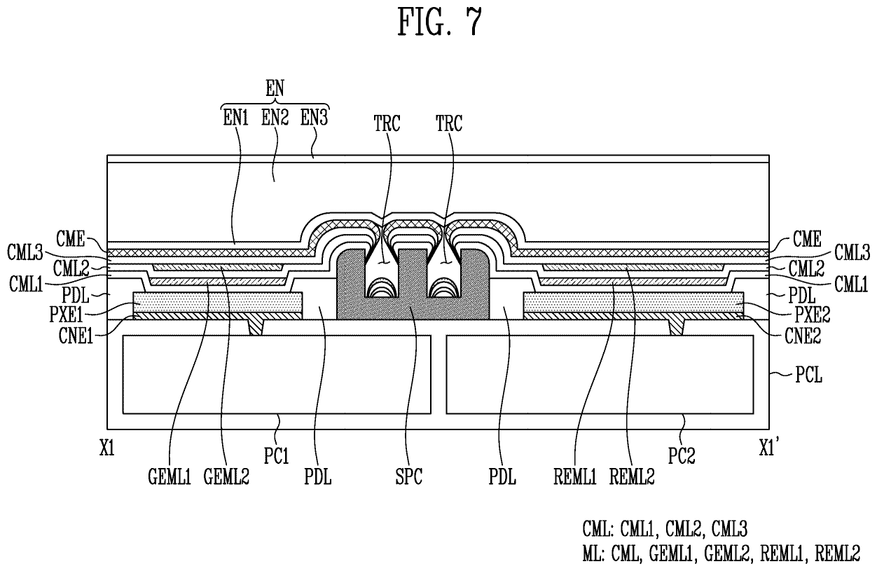

Hereinafter, the role of the spacer SPC and the trench TRC defined in the spacer SPC will be described in more detail with reference to FIG. 7.

FIG. 7 illustrates a cross-sectional view taken along the line X1-X1′ of FIG. 6, according to some embodiments of the present disclosure.

In FIG. 7, for better comprehension and ease of description, the first pixel electrode PXE1, the second pixel electrode PXE2, and the spacer SPC disposed between the first pixel electrode PXE1 and the second pixel electrode PXE2 will be mainly described. Here, the contents to be described later may be applied in substantially the same (or similar) manner to the other pixel electrodes other than the first pixel electrode PXE1 and the second pixel electrode PXE2 and the spacer SPC disposed between them.

Referring to FIG. 7, a pixel circuit layer PCL including a first pixel circuit PC1 and a second pixel circuit PC2 may be provided. Each of the first pixel circuit PC1 and the second pixel circuit PC2 may correspond to the pixel circuit PC described with reference to FIG. 2. The first pixel circuit PC1 may be included in the first pixel (e.g., PX1 in FIG. 1), and the second pixel circuit PC2 may be included in the second pixel (e.g., PX2 in FIG. 1).

A first connection electrode CNE1 and a second connection electrode CNE2 may be disposed on the pixel circuit layer PCL. The connection electrodes CNE1 and CNE2 may be disposed to be spaced apart from each other. The connection electrodes CNE1 and CNE2 may be connected to the pixel circuits PC1 and PC2 included in the pixel circuit layer PCL. For example, the first connection electrode CNE1 may be connected to the first pixel circuit PC1, and the second connection electrode CNE2 may be connected to the second pixel circuit PC2.

In some embodiments, the first connection electrode CNE1 and the second connection electrode CNE2 may include a conductive oxide. For example, the first connection electrode CNE1 and the second connection electrode CNE2 may include an ITO, an IGO, an IGZO, and/or the like. The first connection electrode CNE1 and the second connection electrode CNE2 may have a single-layer or multi-layer structure including the above-described materials.

The first pixel electrode PXE1 and the second pixel electrode PXE2 may be directly disposed on the first connection electrode CNE1 and the second connection electrode CNE2 to correspond one-to-one to the first connection electrode CNE1 and the second connection electrode CNE2. For example, the first pixel electrode PXE1 may be directly disposed on the first connection electrode CNE1, and the second pixel electrode PXE2 may be directly disposed on the second connection electrode CNE2. The first pixel electrode PXE1 may be electrically connected to the first pixel circuit PC1 through the first connection electrode CNE1, and the second pixel electrode PXE2 may be electrically connected to the second pixel circuit PC2 through the second connection electrode CNE2.

In some embodiments, each of the first pixel electrode PXE1 and the second pixel electrode PXE2 may completely overlap a corresponding connection electrode among the connection electrodes CNE1 and CNE2 in a plan view. For example, the first pixel electrode PXE1 may completely overlap the first connection electrode CNE1 in a plan view, and thus the first connection electrode CNE1 disposed under the first pixel electrode PXE1 in a plan view of FIG. 6 may be completely covered by the first pixel electrode PXE1. In this case, the entire lower surface of the first pixel electrode PXE1 may directly contact the entire upper surface of the first connection electrode CNE1.

Although only the first connection electrode CNE1 and the second connection electrode CNE2 are illustrated in FIG. 7, connection electrodes may also be provided for all the pixel electrodes (for example, PXE3, PXE4, and the like) illustrated in FIG. 6, and descriptions of the first connection electrode CNE1 and the second connection electrode CNE2 described with reference to FIG. 7 may be applied in the same (or similar) manner.

The spacer SPC may be disposed on the pixel circuit layer PCL. The spacer SPC may be disposed between the first pixel electrode PXE1 and the second pixel electrode PXE2. The spacer SPC may be disposed to be spaced apart from the first pixel electrode PXE1 and the second pixel electrode PXE2.

In some embodiments, the spacer SPC may be directly disposed on the pixel circuit layer PCL. That is, the spacer SPC directly contacts the pixel circuit layer PCL, and no other configuration may be interposed between the spacer SPC and the pixel circuit layer PCL.

In some embodiments, the spacer SPC may include an organic insulating material. For example, the spacer SPC may include an acryl resin, an epoxy resin, a polyamide resin, a polyimide resin, and/or the like. The spacer SPC may have a single-layer or multi-layer structure including the above-described materials.

In the spacer SPC, at least one trench TRC recessed in a direction from the upper surface of the spacer SPC toward the pixel circuit layer PCL may be defined. For example, as shown in FIG. 7, two trenches TRC may be defined in the spacer SPC. However, the present disclosure is not limited thereto, and one or three or more trenches (e.g., three or more parallel trenches) TRC may be defined in the spacer SPC. When a plurality of trenches TRC are defined, the trenches TRC may be arranged along a separation direction between the first pixel electrode PXE1 and the second pixel electrode PXE2.

A pixel defining film PDL may be disposed on the pixel circuit layer PCL. The pixel defining film PDL may be disposed between the spacer SPC and the pixel electrodes PXE1 and PXE2. The pixel defining film PDL exposes the upper surface of the pixel electrodes PXE1 and PXE2 and may be disposed along the circumference of the pixel electrodes PXE1 and PXE2. In this case, the pixel defining film PDL may cover at least side surfaces of the connection electrodes CNE1 and CNE2 and the pixel electrodes PXE1 and PXE2. The pixel defining film PDL may serve to partition a light emitting area of each pixel.

In some embodiments, the pixel defining film PDL may be directly disposed on the pixel circuit layer PCL between the spacer SPC and the pixel electrodes PXE1 and PXE2. That is, the pixel defining film PDL may be in direct contact with the pixel circuit layer PCL between the spacer SPC and the pixel electrodes PXE1 and PXE2.

In some embodiments, the pixel defining film PDL may include an organic insulating material. For example, the pixel defining film PDL may include a polyacrylic compound, a polyimide compound, a fluorine-based carbon compound such as Teflon, a benzocyclobutene compound, and/or the like.

The intermediate layer ML may be disposed on the above-described elements CNE1, CNE2, PXE1, PXE2, PDL, and SPC. The intermediate layer ML may include a common layer CML disposed on the entire pixel circuit layer PCL.

In detail, the common layer CML may include the first common layer CML1, the second common layer CML2, and the third common layer CML3 that are sequentially stacked. Here, the intermediate layer ML may include the first green light emitting layer GEML1 interposed between the first common layer CML1 and the second common layer CML2, and the second green light emitting layer GEML2 interposed between the second common layer CML2 and the third common layer CML3 in the region, in an area overlapping the first pixel electrode PXE1 (that is, the light emitting area of the first pixel PX1 described with reference to FIG. 1). In addition, the intermediate layer ML may include the first red light emitting layer REML1 interposed between the first common layer CML1 and the second common layer CML2, and the second red light emitting layer REML2 interposed between the second common layer CML2 and the third common layer CML3 in the region, in an area overlapping the second pixel electrode PXE2 (that is, the light emitting area of the second pixel PX2 described with reference to FIG. 1).

The common layer CML may be disconnected in an area in which the trench TRC is defined. Accordingly, it is possible to prevent or substantially reduce a lateral leakage current from occurring between the first pixel electrode PXE1 and the second pixel electrode PXE2, which are adjacent to each other, through the common layer CML.

In this case, the common layer CML may not be substantially disconnected in another area in which the trench TRC is not defined in a plan view of FIG. 6. Accordingly, the common layer CML may be connected through the area in which the trench TRC is not defined. As such, the trench TRC may be selectively defined only in an area in which the shortest path in a plan view between two adjacent pixel electrodes PXE1 and PXE2 is defined. Accordingly, the common layer CML may be connected through the area in which the trench TRC is not defined, and the occurrence of the lateral leakage current described above may be effectively prevented or substantially reduced.

The common electrode layer CME may be disposed on the intermediate layer ML. In some embodiments, the common electrode layer CME may be disconnected (e.g., physically disconnected) in the area in which the trench TRC is defined. Accordingly, it is possible to prevent or substantially reduce a lateral leakage current from occurring through the common electrode layer CME between the first pixel electrode PXE1 and the second pixel electrode PXE2, which are adjacent to each other. In some other embodiments, when the lateral leakage current through the common electrode layer CME is not substantially a problem, the common electrode layer CME may not be disconnected (e.g., may be continuously formed) in the area in which the trench TRC is defined. For example, the common electrode layer CME may have a cross-sectional shape similar to a cross-sectional shape of a first encapsulation layer EN1 to be described later.

An encapsulation layer EN may be disposed on the common electrode layer CME. The encapsulation layer EN may serve to block the intrusion of moisture and gas introduced from the outside.

In some embodiments, the encapsulation layer EN may include the first encapsulation layer EN1, a second encapsulation layer EN2, and a third encapsulation layer EN3 sequentially stacked.

The first encapsulation layer EN1 and the third encapsulation layer EN3 may include an inorganic insulating material. The second encapsulation layer EN2 may include an organic insulating material. Here, each of the first to third encapsulation layers EN1, EN2, and EN3 may not be disconnected (e.g., may be continuously formed) in the area in which the trench TRC is defined.

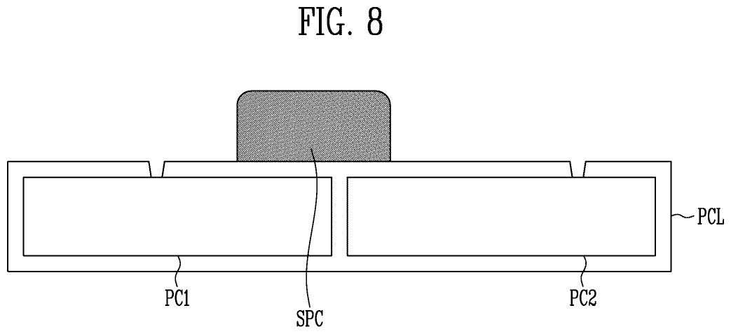

FIGS. 8 to 13 illustrate a method of manufacturing the display device of FIG. 7, according to some embodiments of the present disclosure. In FIG. 8 to FIG. 13, redundant descriptions corresponding to the contents disclosed with reference to FIG. 1 to FIG. 7 may not be repeated.

Referring to FIG. 8, the pixel circuit layer PCL including the first pixel circuit PC1 and the second pixel circuit PC2 may be formed. Through-holes for connection to the first pixel circuit PC1 and the second pixel circuit PC2 may be formed in the pixel circuit layer PCL.

Thereafter, the spacer SPC may be formed on the pixel circuit layer PCL. Here, the trench TRC may not be formed in the spacer SPC.

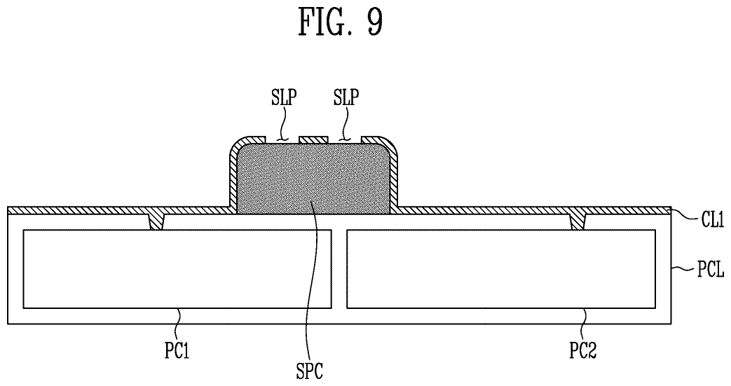

Referring to FIG. 9, after a first conductive layer CL1 is entirely formed on the pixel circuit layer PCL, at least one slit pattern (e.g., two slit patterns) SLP exposing a portion of the spacer SPC may be formed by patterning the first conductive layer CL1. Here, the slit pattern SLP may be formed at a position corresponding to the trench TRC described with reference to FIG. 7.

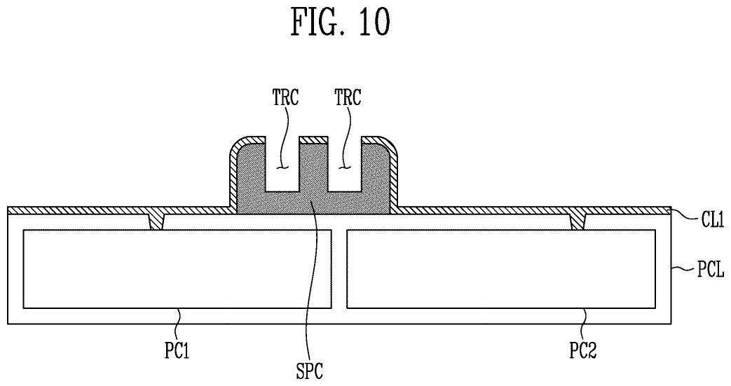

Referring to FIG. 10, the trench TRC may be formed by etching the spacer SPC exposed by the slit pattern SLP. Here, the first conductive layer CL1 may serve as a mask. There is no limitation on a method of etching the spacer SPC, and various suitable known etching methods may be applied.

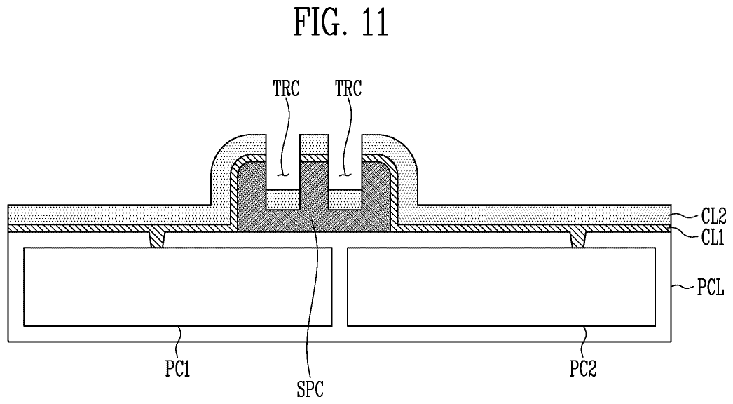

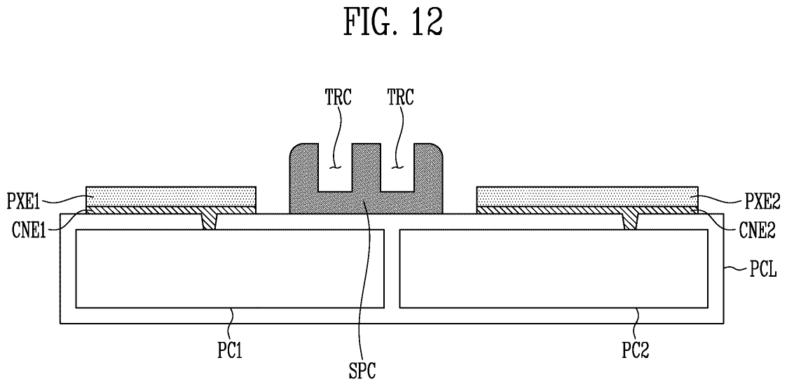

Referring to FIGS. 11 and 12, after a second conductive layer CL2 is entirely formed, the first conductive layer CL1 and the second conductive layer CL2 may be patterned to form the connection electrodes CNE1 and CNE2 and the pixel electrodes PXE1 and PXE2. The patterning of the first conductive layer CL1 and the second conductive layer CL2 may be performed concurrently (e.g., substantially simultaneously). There is no limitation on a method of patterning the first conductive layer CL1 and the second conductive layer CL2, and various suitable known patterning methods of the conductive layer may be applied.

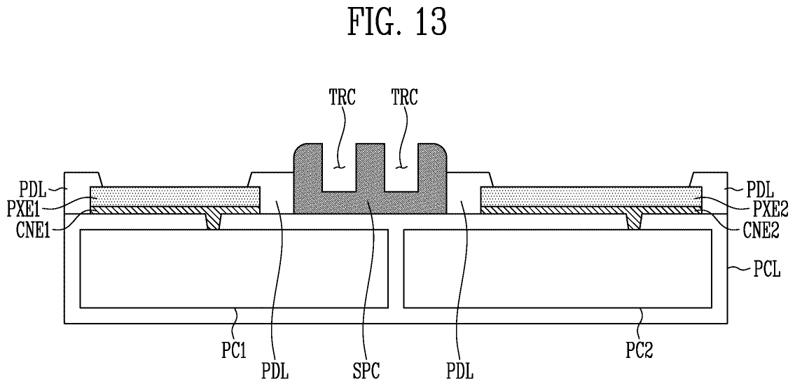

Referring to FIG. 13, the pixel defining film PDL may be formed. A method of forming the pixel defining film PDL is not particularly limited. For example, after entirely applying an organic material configuring the pixel defining film PDL to an area other than the spacer SPC, a method of removing a portion of the organic material to expose at least a portion of the upper surfaces of the pixel electrodes PXE1 and PXE2 may be applied.

After the operation described with reference to FIG. 13, forming the intermediate layer ML may be further performed. The intermediate layer ML may include the common layer CML entirely disposed on the pixel circuit layer PCL. The common layer CML may be formed by, for example, a batch deposition method, and in this case, the common layer CML may be disconnected in an area in which the trench TRC is defined by a step of the trench TRC.

Thereafter, forming the common electrode layer CME may be further performed. The common electrode layer CME may be entirely disposed on the pixel circuit layer PCL. The common electrode layer CME may be formed by, for example, a batch deposition method, and in this case, the common electrode layer CME may be disconnected in an area in which the trench TRC is defined by a step of the trench TRC.

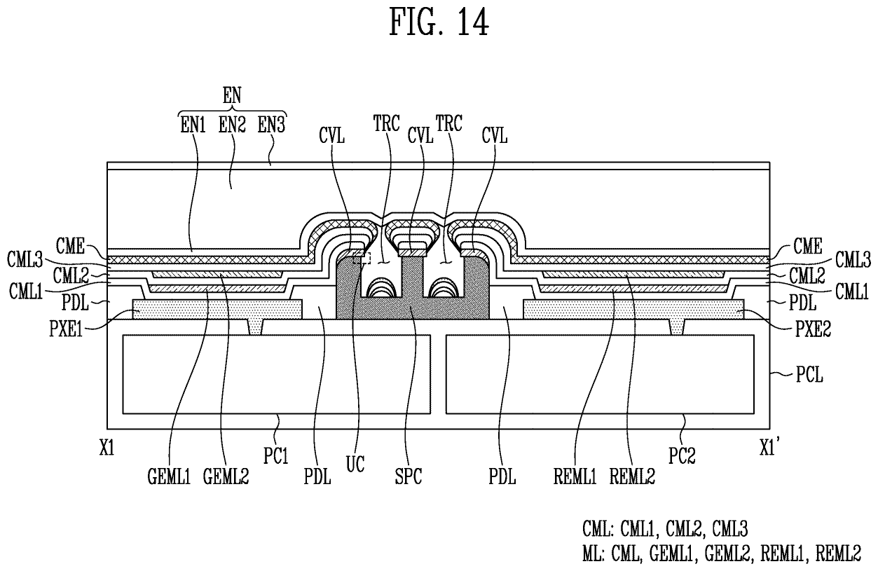

FIG. 14 illustrates a cross-sectional view taken along the line X1-X1′ of FIG. 6, according to some other embodiments of the present disclosure. Hereinafter, redundant descriptions corresponding to the contents described with reference to FIG. 7 may not be repeated.

Referring to FIG. 14, unlike the display device according to some embodiments of the present disclosure described with reference to FIG. 7, the connection electrodes CNE1 and CNE2 may not be disposed below the pixel electrodes PXE1 and PXE2. That is, the connection electrodes CNE1 and CNE2 may be omitted. In this case, each of the pixel electrodes PXE1 and PXE2 may be connected to a corresponding pixel circuit among the pixel circuits PC1 and PC2, and the pixel defining film PDL may be disposed to cover at least a side surface of each of the pixel electrodes PXE1 and PXE2.

In addition, unlike the display device according to the some embodiments of the present disclosure described with reference to FIG. 7, a spacer cover layer CLV may be disposed on the spacer SPC.

The spacer cover layer CVL may cover at least the upper surface of the spacer SPC. An opening that overlaps the trench TRC may be defined in the spacer cover layer CVL. In this case, a cross-sectional width of the opening may be smaller than that of the trench TRC adjacent to the opening. Accordingly, an undercut structure UC may be defined between the spacer cover layer CVL and the spacer SPC.

As such, as the undercut structure UC is defined, the common layer CML may be more effectively disconnected in the area in which the trench TRC is defined. Likewise, the common electrode layer CME may be more effectively disconnected in the area in which the trench TRC is defined.

In some embodiments, the spacer cover layer CVL may include an inorganic insulating material. For example, the spacer cover layer CVL may include a silicon oxide, a silicon nitride, a silicon oxynitride, and/or the like. When the spacer cover layer CVL includes the inorganic insulating material, the spacer cover layer CVL may extend from the upper surface of the spacer SPC and may be disposed to be in contact with each of the pixel electrodes PXE1 and PXE2. In some other embodiments, the spacer cover layer CVL may include a metallic material or a conductive oxide. For example, the spacer cover layer CVL may include titanium, aluminum, silver, gold, an ITO, an IZO, ZnO, an ITZO, and/or the like. When the spacer cover layer CVL includes a metallic material or a conductive oxide, the spacer cover layer CVL may be disposed to be spaced apart from each of the pixel electrodes PXE1 and PXE2.

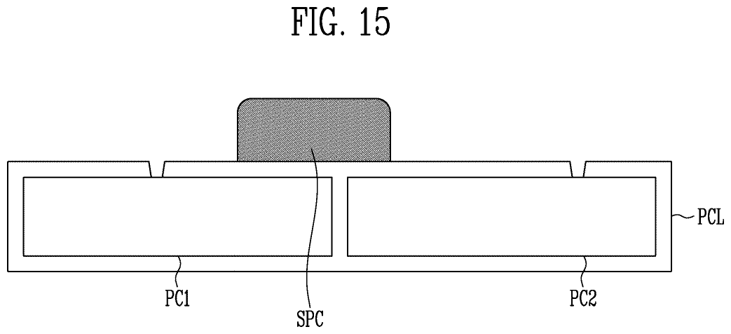

FIGS. 15 to 21 illustrate a method of manufacturing the display device of FIG. 14, according to some embodiments of the present disclosure. In FIGS. 15 to 21, redundant descriptions corresponding to the contents disclosed with reference to FIGS. 1 to 7 and FIG. 14 may not be repeated.

Referring to FIG. 15, the pixel circuit layer PCL including the first pixel circuit PC1 and the second pixel circuit PC2 may be formed. Through-holes for connection to the first pixel circuit PC1 and the second pixel circuit PC2 may be formed in the pixel circuit layer PCL.

Thereafter, the spacer SPC may be formed on the pixel circuit layer PCL. Here, the trench TRC may not be formed in the spacer SPC.

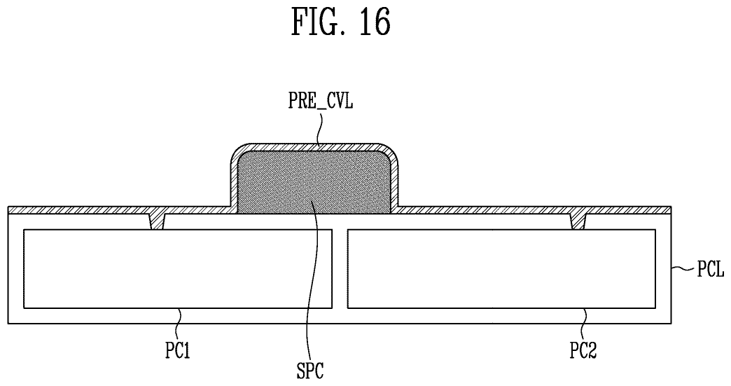

Referring to FIG. 16, a preliminary spacer cover layer PRE_CVL may be entirely formed on the pixel circuit layer PCL. The preliminary spacer cover layer PRE_CVL may include the same or substantially the same material as the spacer cover layer CVL described with reference to FIG. 14.

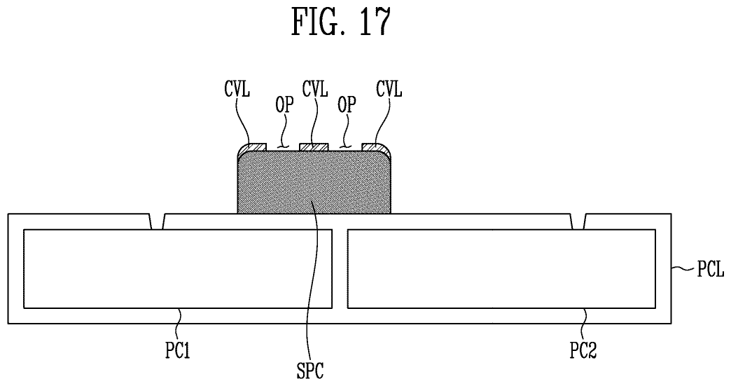

Referring to FIG. 17, the preliminary spacer cover layer PRE_CVL (see also, PRE_CVL in FIG. 16) may be patterned to form the spacer cover layer CVL defining at least one opening OP covering at least an upper surface of the spacer SPC and exposing at least a portion of the spacer SPC. Here, the opening OP may be formed at a position corresponding to the trench TRC described with reference to FIG. 14.

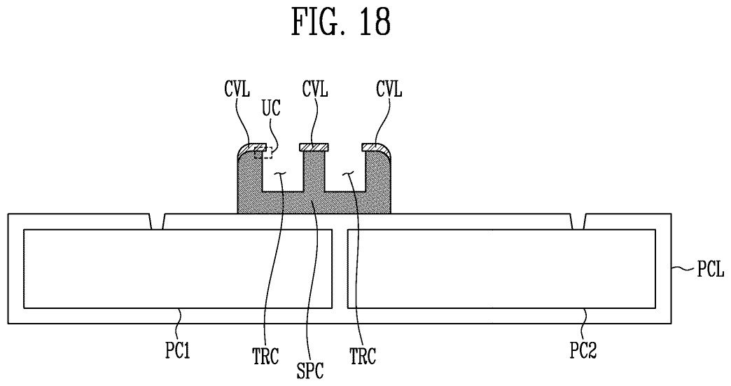

Referring to FIG. 18, the trench TRC may be formed by etching the spacer SPC exposed by the opening (see e.g., OP in FIG. 17). Here, the spacer cover layer CVL may serve as a mask.

In the process of performing the etching process of forming the trench TRC, the spacer SPC may be etched relatively more. Accordingly, the undercut structure UC may be defined between the spacer cover layer CVL and the spacer SPC.

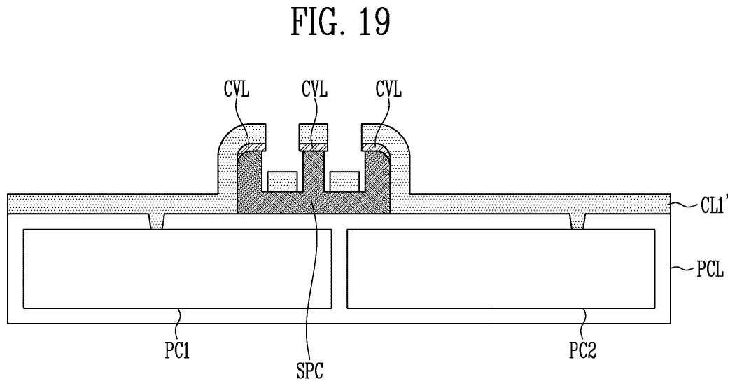

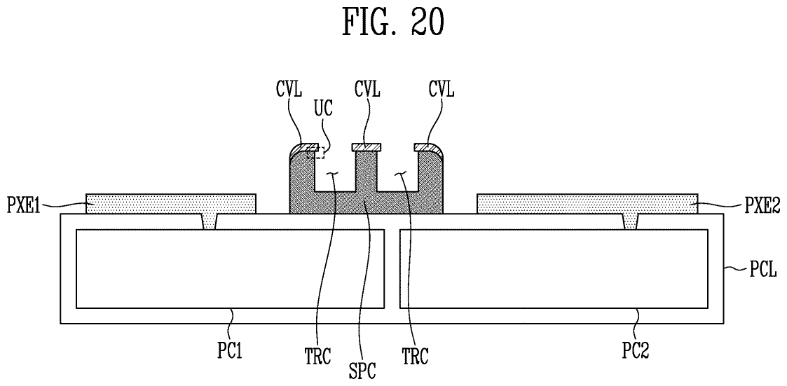

Referring to FIG. 19 and FIG. 20, after the first conductive layer CL1′ is entirely formed, the pixel electrodes PXE1 and PXE2 may be formed by patterning a first conductive layer CL1′. There is no limitation on a method of patterning the first conductive layer CL1′, and various suitable known patterning methods of the conductive layer may be applied.

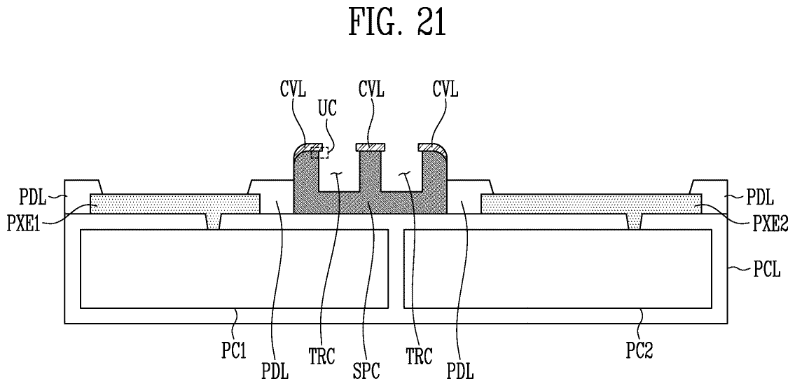

Referring to FIG. 21, the pixel defining film PDL may be formed. A method of forming the pixel defining film PDL is not particularly limited. For example, after entirely applying an organic material configuring the pixel defining film PDL to an area other than the spacer SPC, a method of removing a portion of the organic material to expose at least a portion of the upper surfaces of the pixel electrodes PXE1 and PXE2 may be applied.

After the operation described with reference to FIG. 21, forming the intermediate layer ML may be further performed. The intermediate layer ML may include the common layer CML entirely disposed on the pixel circuit layer PCL. The common layer CML may be formed by, for example, a batch deposition method, and in this case, the common layer CML may be disconnected in an area in which the trench TRC is defined by a step of the trench TRC.

Thereafter, forming the common electrode layer CME may be further performed. The common electrode layer CME may be entirely disposed on the pixel circuit layer PCL. The common electrode layer CME may be formed by, for example, a batch deposition method, and in this case, the common electrode layer CME may be disconnected in an area in which the trench TRC is defined by a step of the trench TRC.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a pixel circuit layer;
a plurality of connection electrodes spaced apart from each other on the pixel circuit layer and connected to a pixel circuit in the pixel circuit layer;
a plurality of pixel electrodes directly on the plurality of connection electrodes to correspond one-to-one to the plurality of connection electrodes and spaced apart from each other;
a spacer between two adjacent pixel electrodes among the plurality of pixel electrodes on the pixel circuit layer; and
a pixel defining film between the spacer and the plurality of pixel electrodes and covering at least a side surface of each of the plurality of connection electrodes and the plurality of pixel electrodes, on the pixel circuit layer,
wherein at least one trench recessed in a direction from an upper surface of the spacer toward the pixel circuit layer is defined in the spacer.

2. The display device of claim 1, wherein each of the plurality of pixel electrodes completely overlaps a corresponding connection electrode among the plurality of connection electrodes in a plan view.

3. The display device of claim 1, wherein the spacer is in direct contact with the pixel circuit layer.

4. The display device of claim 3, wherein the pixel defining film is in direct contact with the pixel circuit layer between the spacer and the plurality of pixel electrodes.

5. The display device of claim 1, wherein in a plan view, the trench extends in a direction crossing a separation direction of two adjacent pixel electrodes among the plurality of pixel electrodes.

6. The display device of claim 1, further comprising:
an intermediate layer on the plurality of pixel electrodes and comprising at least one common layer entirely on the pixel circuit layer; and
a common electrode layer on the intermediate layer.

7. The display device of claim 6, wherein the common layer is disconnected in an area in which the trench is defined.

8. The display device of claim 7, wherein the common electrode layer is disconnected in the area in which the trench is defined.

9. A display device comprising:
a pixel circuit layer;
a plurality of pixel electrodes spaced apart from each other on the pixel circuit layer;
a spacer between two adjacent pixel electrodes among the plurality of pixel electrodes on the pixel circuit layer;
a spacer cover layer covering at least an upper surface of the spacer; and
a pixel defining film between the spacer and the plurality of pixel electrodes and covering at least a side surface of each of the plurality of pixel electrodes, the pixel defining film being on the pixel circuit layer,
wherein the spacer defines at least one trench recessed in a direction from the upper surface of the spacer toward the pixel circuit layer, and
wherein the spacer cover layer defines an opening overlapping the trench, and
wherein an undercut structure is defined between the spacer and the spacer cover layer.

10. The display device of claim 9, wherein the spacer is in direct contact with the pixel circuit layer.

11. The display device of claim 10, wherein the pixel defining film is in direct contact with the pixel circuit layer between the spacer and the plurality of pixel electrodes.

12. The display device of claim 9, wherein in a plan view, the trench extends in a direction crossing a separation direction of two adjacent pixel electrodes among the plurality of pixel electrodes.

13. The display device of claim 9, further comprising:
an intermediate layer on the plurality of pixel electrodes and comprising at least one common layer entirely on the pixel circuit layer; and
a common electrode layer on the intermediate layer.

14. The display device of claim 13, wherein the common layer is disconnected in an area in which the trench is defined.

15. The display device of claim 14, wherein the common electrode layer is disconnected in the area in which the trench is defined.

16. A method of manufacturing a display device, the method comprising:
forming a spacer on a pixel circuit layer;
entirely forming a first conductive layer, defining at least one slit pattern exposing a portion of the spacer, on the pixel circuit layer;
forming a trench by etching the spacer exposed by the slit pattern;
entirely forming a second conductive layer on the first conductive layer;
forming, by patterning the first conductive layer and the second conductive layer, a plurality of connection electrodes spaced apart from each other with at least the spacer therebetween, and a plurality of pixel electrodes directly on the plurality of connection electrodes to correspond one-to-one to the plurality of connection electrodes; and
forming a pixel defining film that is between the spacer and the plurality of pixel electrodes and covers at least a side surface of each of the plurality of connection electrodes and the plurality of pixel electrodes, the pixel defining film being on the pixel circuit layer.

17. The method of manufacturing the display device of claim 16, further comprising:
forming an intermediate layer comprising at least one common layer entirely on the pixel circuit layer, the intermediate layer being on the plurality of pixel electrodes.

18. The method of manufacturing the display device of claim 17, wherein the common layer is disconnected in an area in which the trench is defined.

19. The method of manufacturing the display device of claim 17, further comprising:
forming a common electrode layer on the intermediate layer.

20. The method of manufacturing the display device of claim 19, wherein the common electrode layer is disconnected in an area in which the trench is defined.

21. A method of manufacturing a display device, the method comprising:
forming a spacer on a pixel circuit layer;
forming a spacer cover layer covering at least an upper surface of the spacer and defining at least one opening exposing at least a portion of the spacer, the spacer cover layer being on the pixel circuit layer;
forming a trench by etching the spacer exposed by the opening;
forming a plurality of pixel electrodes spaced apart from each other with at least the spacer therebetween; and
forming a pixel defining film that is between the spacer and the plurality of pixel electrodes and covers at least a side surface of each of the plurality of pixel electrodes, the pixel defining film being on the pixel circuit layer,
wherein an undercut structure is defined between the spacer and the spacer cover layer.

22. The method of manufacturing the display device of claim 21, further comprising:
forming an intermediate layer comprising at least one common layer entirely on the pixel circuit layer, the intermediate layer being on the plurality of pixel electrodes.

23. The method of manufacturing the display device of claim 22, wherein the common layer is disconnected in an area in which the trench is defined.

24. The method of manufacturing the display device of claim 22, further comprising:
forming a common electrode layer on the intermediate layer.

25. The method of manufacturing the display device of claim 24, wherein the common electrode layer is disconnected in an area in which the trench is defined.
